(19) United States
(12) Patent Application Publication
(10) Pub. No.: US 2009/0219752 A1
(43) Pub. Date: Sep. 3, 2009

(54) Apparatus and Method for Improving Storage Latch Susceptibility to Single Event Upsets

(76) Inventor: Larry Wissel, Williston, VT (US)

Correspondence Address: CANTOR COLBURN LLP-IBM BURLINGTON, 20 Church Street, 22nd Floor, Hartford, CT, 06103, US

(21) Appl. No.: 12/039,119

(22) Filed: Feb. 28, 2008

(51) Int. Cl. G11C 11/413; H03K 19/003

(52) U.S. Cl. 365/154; 326/9

(57) ABSTRACT

An apparatus for improving storage latch susceptibility to single event upsets includes a dual interconnected storage cell (DICE) configured within a storage latch circuit; a pair of separate three-state circuits configured to write the DICE latch, with each three-state circuit coupled to separate data nodes within the DICE latch; and a pair of local clock circuits configured within the storage latch circuit, the pair of local clock circuits configured to generate a duplicate pair of control signals that separately control a corresponding one of the separate three-state circuits. In the event of a charge accumulation event on only one of the pair of local clock circuits so as to change the logical state of the corresponding control signal, the presence of the other of the pair of local clock circuits that remains unaffected by the charge accumulation event prevents an error in the logical state of the DICE latch.

### BACKGROUND OF THE INVENTION

The present invention relates generally to integrated circuit (IC) memory devices and, more particularly, to an apparatus and method for improving storage latch susceptibility to single event upsets (SEUs).

The effects of radiation on integrated circuits have been known for many years. These effects may be broken down into two broad categories, namely “total dose effects,” in which an integrated circuit gradually deteriorates due to the accumulated effect of all the damage done to the crystal structure by the many particles incident thereupon, and “single event effects” in which a single particle (either through its exceptionally high energy or through the accuracy of its trajectory through a semiconductor) is capable of affecting a circuit. Single event effects are varied, and most of the effects can be mitigated by proper layout techniques. One type of single-event effect that requires more effort to eliminate is the single event upset, or SEU, in which the contents of a memory cell are altered by an incident particle.

SEUs belong to a class of errors called “soft-errors” in that they simply reverse the logical state of devices such as storage latches. Although SEUs do not, in and of themselves, physically damage a circuit, they are capable of propagating through combinational logic and being stored in memory. In turn the operation of a circuit may be altered in such a way so as to cause an error in logic function, potentially crashing a computer system.

A number of SEU-hardening techniques have thus been developed. These techniques may be categorized into three general types: (1) technology hardening, in which changes are made to the fabrication processes of the chip such that critical charges necessary for single-event upsets to occur do so with reduced frequency (e.g., using Silicon-on-Sapphire or SOS substrates to reduce the charge build-up due to incident particles); (2) passive hardening in which passive components such as capacitors or resistors are added to a circuit to either slow it down or to increase the charge required to reverse its state; and (3) design hardening in which redundancy and feedback elements are added to a circuit to make it more immune to single events.

Technology hardening is generally not commercially viable due to the expense associated with designing and improving existing fabrication methods, which can cost billions of dollars to develop in the first place. Moreover, passive hardening is not efficient. Although it is a workable solution, it represents a deliberate slowing-down of information processing, which is at odds with the clear industry objective to speed up processing. Passive hardening is also not scalable, meaning that fabrication changes necessarily result in passive hardening redesign and re-testing. Accordingly, it is desirable to be able continue to improve design hardening techniques in order to combat SEU difficulties as semiconductor devices continue to scale.

### BRIEF SUMMARY OF THE INVENTION

The foregoing discussed drawbacks and deficiencies of the prior art are overcome or alleviated, in an exemplary embodiment, by an apparatus for improving storage latch susceptibility to single event upsets (SEUs), including a dual interconnected storage cell (DICE) configured within a storage latch circuit; a pair of separate three-state circuits configured to write the DICE latch, with each three-state circuit coupled to separate data nodes within the DICE latch; and a pair of local clock circuits configured within the storage latch circuit, the pair of local clock circuits configured to generate a duplicate pair of control signals that separately control a corresponding one of the pair of the separate three-state circuits configured to write the DICE latch; wherein in the event of a charge accumulation event on only one of the pair of local clock circuits so as to change the logical state of the corresponding control signal, the presence of the other of the pair of local clock circuits that remains unaffected by the charge accumulation event prevents an error in the logical state of the DICE latch.

In another embodiment, a design structure embodied in a machine readable medium used in a design process includes an apparatus for improving storage latch susceptibility to single event upsets (SEUs), the apparatus including a dual interconnected storage cell (DICE) configured within a storage latch circuit; a pair of separate three-state circuits configured to write the DICE latch, with each three-state circuit coupled to separate data nodes within the DICE latch; and a pair of local clock circuits configured within the storage latch circuit, the pair of local clock circuits configured to generate a duplicate pair of control signals that separately control a corresponding one of the pair of the separate three-state circuits configured to write the DICE latch; wherein in the event of a charge accumulation event on only one of the pair of local clock circuits so as to change the logical state of the corresponding control signal, the presence of the other of the pair of local clock circuits that remains unaffected by the charge accumulation event prevents an error in the logical state of the DICE latch.

In still another embodiment, a method for improving storage latch susceptibility to single event upsets (SEUs) includes configuring a dual interconnected storage cell (DICE) configured within a storage latch circuit; configuring a pair of separate three-state circuits configured to write the DICE latch, with each three-state circuit coupled to separate data nodes within the DICE latch; and configuring a pair of local clock circuits configured within the storage latch circuit, the pair of local clock circuits configured to generate a duplicate pair of control signals that separately control a corresponding one of the pair of the separate three-state circuits configured to write the DICE latch; wherein in the event of a charge accumulation event on only one of the pair of local clock circuits so as to change the logical state of the corresponding control signal, the presence of the other of the pair of local clock circuits that remains unaffected by the charge accumulation event prevents an error in the logical state of the DICE latch.

### BRIEF DESCRIPTION OF THE DRAWINGS

Referring to the exemplary drawings wherein like elements are numbered alike in the several Figures:

FIG. 1 is a schematic diagram of a conventional storage latch and associated three-state write circuit;

FIG. 2 is a schematic diagram of a conventional dual interconnected storage latch and associated three-state write circuit pair;

FIG. 3 is a schematic diagram of an apparatus for improving storage latch susceptibility to indirect single event upsets (SEUs), in accordance with an embodiment of the invention;

FIG. 4 is a schematic diagram of a two-port latch version of the apparatus of FIG. 3, in accordance with an alternative embodiment of the invention;

FIG. 5 is a schematic diagram of set of existing local control signals for a dual port, master/slave flip-flop;

FIG. 6 is a schematic diagram of a corresponding set of duplicate control signals of those shown in FIG. 5, in accordance with the inventive embodiments discussed herein; and

FIG. 7 is a flow diagram of an exemplary design process used in semiconductor design, manufacturing, and/or test.

### DETAILED DESCRIPTION OF THE INVENTION

Disclosed herein is an apparatus, method and design structure for improving storage latch susceptibility to single event upsets (SEUs) and, in particular, indirect-mechanism upsets such as those caused by glitches on intra-cell extensions of a clock tree that are characterized by relatively low-drive, low-capacitance devices. Briefly stated, the invention embodiments presented herein utilize replication of a local clock tree node such that charge collection in a single node in the clock tree structure does not upset a latch, particularly for a dual interconnected latch that is conventionally resistant to direct upset mechanisms, but not to indirect upset mechanisms.

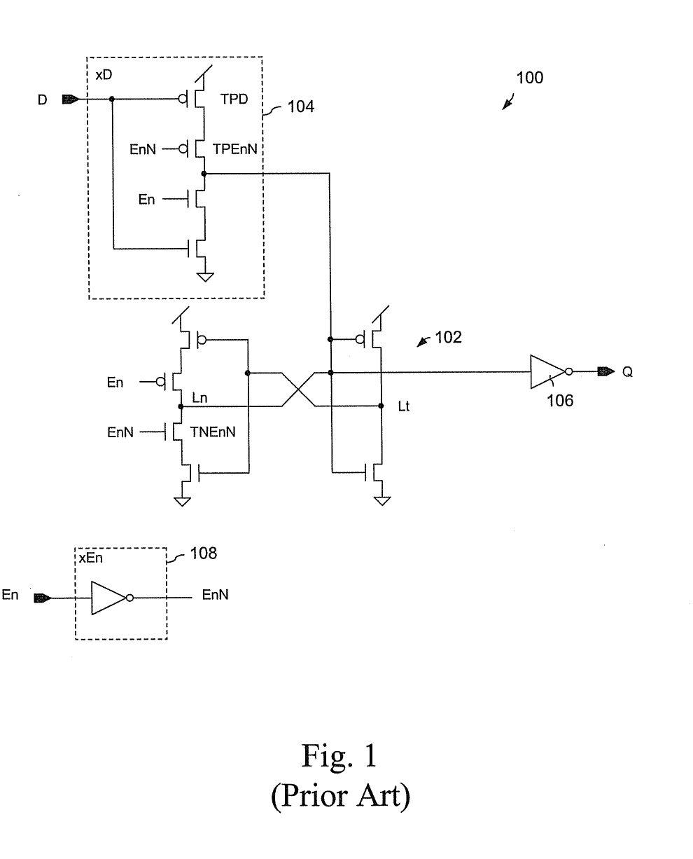

Referring initially to FIG. 1, there is shown a schematic diagram of conventional storage latch and associated three-state write circuit, designated collectively by reference number 100. The configuration of the latch 102, including a pair of cross-coupled complementary metal oxide semiconductor (CMOS) inverters, is well known in the art. The true data node is labeled Lt, while the complement data node is labeled Ln in FIG. 1. In addition, the three-state circuit 104 (also labeled xD in FIG. 1), when enabled by a high-going control signal (En) is configured to write data into the latch 102. An output buffer 106 inverts the value of the data on the complement node Ln so as to produce a true data signal on output pin Q.

It is also well known that such a latch may be upset by collected charge in the event that a charged particle passes through the silicon lattice near one of the storage nodes of the latch 102. In other words, the latch 102 is subject to soft errors. As used herein, a “direct upset” mechanism refers to an upset caused by charge collection at a storage node of the latch itself (e.g., node Ln or Lt in FIG. 1). In 65 nanometer (nm) technology, a charge as low as 2 femtocouloumbs (fC) can upset a latch stage in a typical flip-flop. As also used herein, an “indirect upset” mechanism refers to an upset caused by charge collection in locations other than the storage node(s) itself, such as charge collection in the clock tree, for example. This mechanism is very unlikely to occur in an inter-cell clock tree, because the drive strength of clock tree buffers is relatively high, as is the capacitance of the clock tree nodes themselves. However, intra-cell extensions of the clock tree, such as the inverter xEn 108 shown in FIG. 1, are neither high-drive nor high-capacitance.

Regarding the operation of the latch 102 of FIG. 1, when control signal En=0, the latch 102 is opaque with respect to the three-state circuit 104 (i.e., a high-impedance path exists between the three-state circuit 104 and storage node Ln. More specifically, when En=0, then EnN=1, thereby turning transistor TPEnN off and preventing the input signal, D, of the three-state circuit 104 from disturbing the state of the latch 102 even when D=0 and transistor TPD is on. On the other hand, if the inverter xEn 108 happens to collects negative charge at a point in time when the output of the inverter xEN is high (i.e., EnN=1), then the output EnN may be caused a glitch to a logical 0. A negative charge of 10 fC may create a glitch on EnN of sufficient amplitude and pulsewidth so as to turn transistor TPEnN of the three-state circuit 104 on (with transistor TPD already being on) to pull complementary date node Ln high. It will be noted that a glitch on EnN from logical 1 to logical 0 will also turn interlock transistor TNEnN in the latch 102 off, so that the series combination TPD-TPEnN in the three-state circuit 104 is not opposed by a pull-down transistor in the latch itself. It will thus be seen that the conventional cross-coupled latch 102 of FIG. 1 is susceptible to both a “direct upset” of one of the storage nodes of the latch itself, as well as to an “indirect upset” of a control circuit node within the latch circuitry, such as an internal clock tree node.

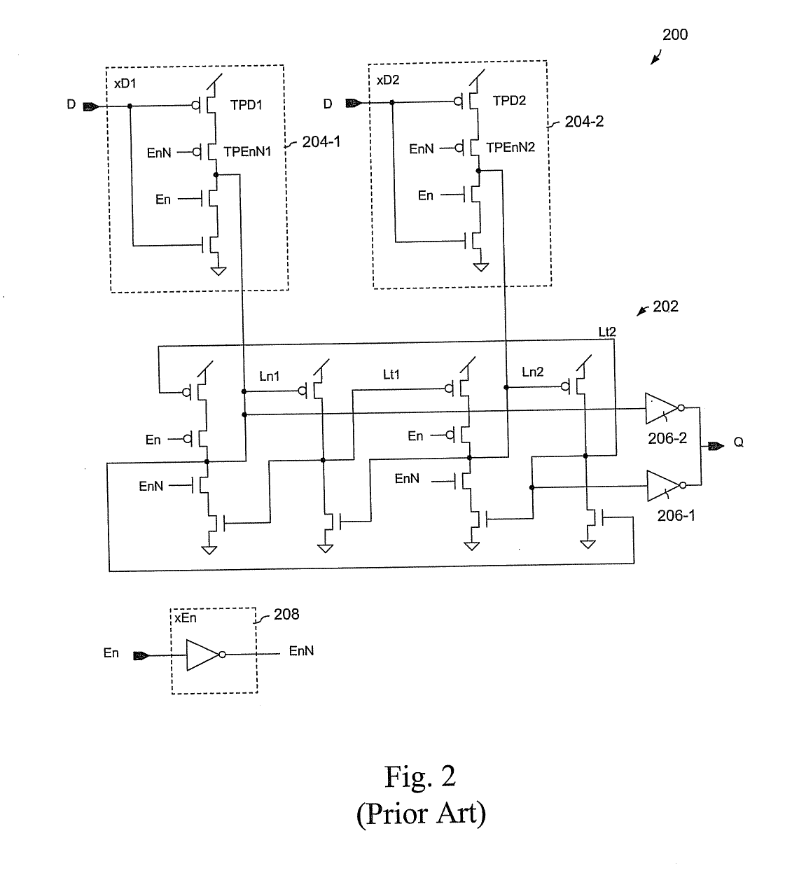

One existing approach to rendering a storage latch more robust with respect to soft error upsets is through the use of the so called “DICE” (Dual Interlocked storage CEll) latch. As is known in the art, a DICE latch (in contrast to a single cross-coupled inverter pair with a single true and complement data node) utilizes two pairs of true and complement nodes that are interconnected in a manner such that an upset of a single node of a given polarity does not ultimately disturb the logical state of the cell, so long as the other node of that polarity remains unaffected by a simultaneous SEU event. An example of a conventional DICE latch with an associated pair of three-state write circuits is generally depicted in the circuitry 200 of FIG. 2.

As shown in FIG. 2, the latch 202 includes four nodes, with complement data stored on Ln1 and Ln2, and true data stored on Lt1 and Lt2. Each complement node has its own 3-state circuit 204-1 (xD1) and 204-2 (xD2) associated therewith. The specific details of the DICE latch 202 in normal modes of operation are well known to those skilled in the art, and thus a detailed description of the same is omitted herein. With respect to SEU events, it will be see that in the event charge collection causes a full-rail amplitude disturbance on a single latch node (e.g., Ln1), such disturbance may also cause a full-rail response on one more additional node (e.g., Lt1). However, due to the manner in which the four nodes are interconnected, the two other nodes (e.g., Ln2, Lt2) will retain their original voltages and, once the collected charge is dissipated, the two nodes which were not disturbed (e.g., Ln2, Lt2) will restore the two disturbed nodes (e.g., Ln1, Lt1) to their original state. In contrast with the latch 102 of FIG. 1, DICE latch 202 includes a pair of output buffers 206-1, 206-2, respectively coupled to the complement data nodes Ln1, Ln2. The outputs of buffers 206-1, 206-2 are commonly coupled to the output node Q of DICE latch 202. Since the loads on Ln1 and Ln2 (and therefore on xD1 and xD2) are identical, set-up and hold time characterization is simplified. In addition, if either node Ln1 or Ln2 (but not both) is disturbed, then a potential glitch on Q is suppressed.

It will thus be appreciated that the DICE latch 202 is substantially immune from “direct” storage node upsets. For this to happen, both nodes of the same polarity (e.g., Ln1 and Ln2) must be disturbed. However, the likelihood of such an event is quite low as the collection of charge by two nodes of the same polarity would typically require an exceptionally large amount of charge do accumulate across a wide area.

On the other hand, and as also indicated above, the DICE latch 202 utilizes two three-state circuits 204-1, 204-2 (xD1, xD2) to write the latch. As can be seen from the schematic of FIG. 2, both of these three-state circuits share the common local clock tree buffer 208 (xEn) and, as such, a low-going glitch on EnN will simultaneously activate both of the three-state circuits xD1 and xD2 (i.e., by turning on transistors TPEnN1 and TPEnN2, respectively), which will in turn disturb both complementary data nodes Ln1 and Ln2 in a manner similar to the complementary data node Ln of latch 102 described in FIG. 1. Disturbing two nodes of the same polarity will upset even a DICE latch. In other words, the configuration of a conventional DICE latch, while resistant to direct storage node upsets, is still subject to an “indirect” upset of (for example) a low-drive, low-capacitance control signal node within the latch circuitry.

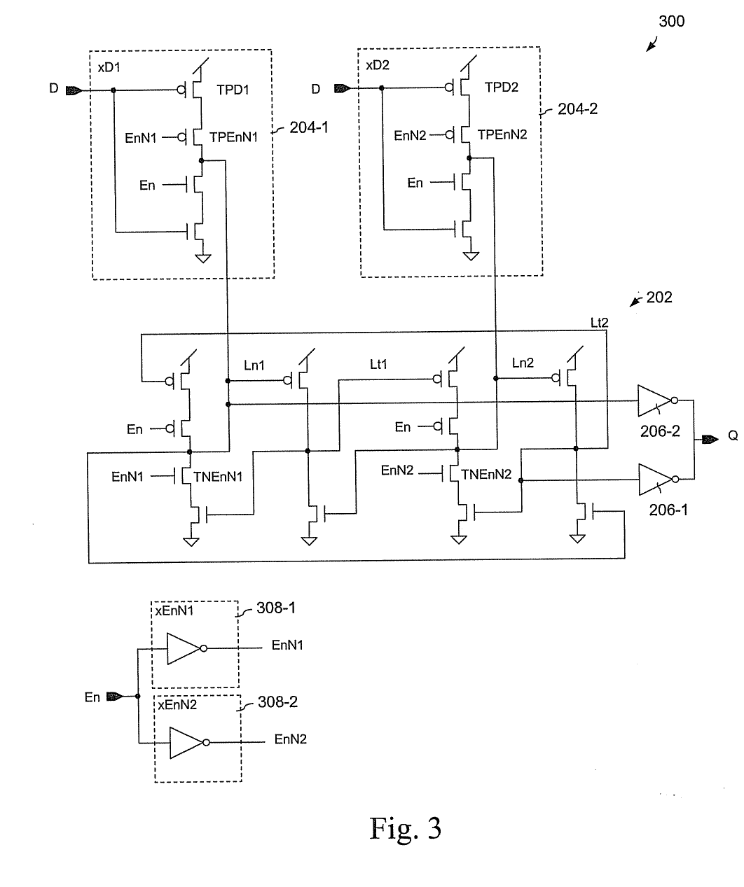

Therefore, in accordance with an embodiment of the invention, FIG. 3 is a schematic diagram of an apparatus 300 for improving storage latch susceptibility to indirect single event upsets. As is shown, FIG. 3 introduces a duplication of the local clock tree structure, in the form of a second inverter (i.e., xEnN2 in addition to xEnN1) such that charge collection by a single node in the clock tree will not upset the operation of the latch 202. Thus, the use of the inverter pair 308-1 (xEnN1), 308-2 (xEnN2) in the exemplary embodiment of FIG. 3 retains the direct-upset robustness of the conventional DICE latch of FIG. 2, but drastically reduces occurrences of the indirect upset mechanism described above.

More specifically, FIG. 3 illustrates how the enable pin En feeds two separate inverters xEnN1 and xEnN2, which in turn drive enable complement nodes EnN1 and EnN2, respectively. A low-going glitch on just one of the two nodes (e.g., on EnN1) will turn on only one of the three-state circuits (e.g., xD1) and thus disturb only one node (e.g., Ln1) of a given polarity. Accordingly, like the direct upset mechanism, the indirect upset mechanism for the design of FIG. 3 can only occur in the rare event that a charged particle deposits an exceptionally large amount of charge across a wide area, so as to cause glitches on both internal latch control signals EnN1 and EnN2.

It is recognized herein that it is possible to implement a connection variant for the DICE latch 202 that further reduces the amplitude of transient noise on the storage nodes when either xEnN1 or xEnN2 collects charge. As is shown, the gate of transistor TNEnN1 of the DICE latch 202 is coupled to EnN1. A low-going glitch on EnN1 will not only turn on TPEnN1 of three-state circuit xD1 and pulling Ln1 high, but will also turn off TNEnN1, which eliminates opposition to the pull up action of xD1. If the gate connections to TNEnN1 and TNEnN2 were to be reversed, then the pull-down transistor TNEnN1 would remain active against the pull-up action of xD1 in trying to pull Ln1 high. However, such a feature is not essential, because the DICE latch 202 is immune to a single node disturbance on Ln1.

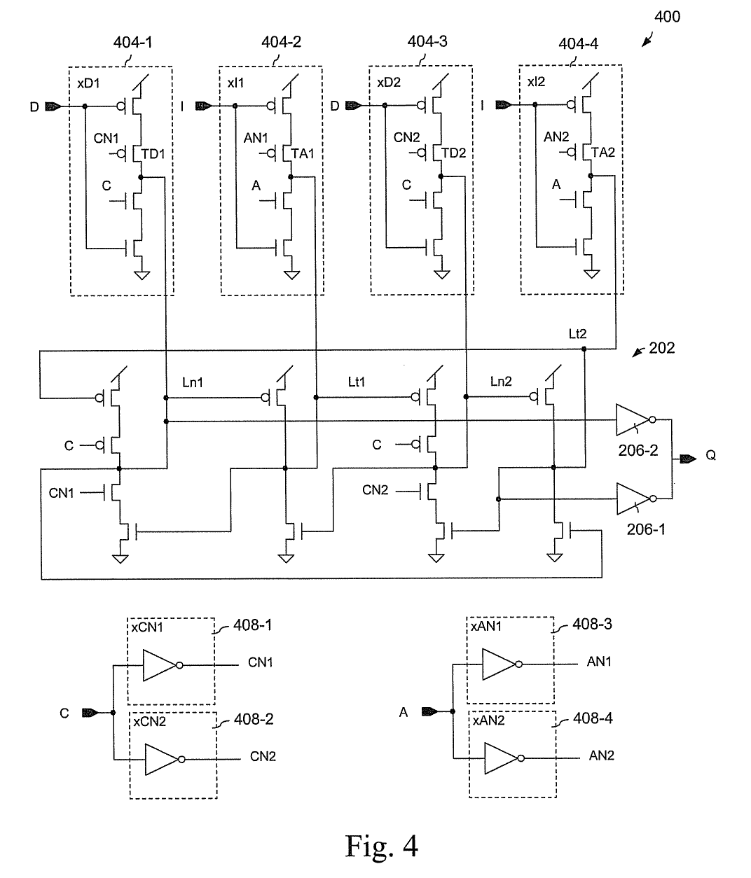

To this point, the exemplary latches discussed herein are single-stage latches, which have limited use. It will therefore be appreciated that the principles herein are also applicable to multiple stage devices, such as master-slave flip-flops (including scan latches), which are far more extensively used. In this regard, FIG. 4 is a schematic diagram of a two-port latch version of the apparatus of FIG. 3, in accordance with an alternative embodiment of the invention. In the apparatus 400 of FIG. 4, the previously designated enable “En” control signal is renamed “C” with the complement signals thereof labeled CN1, CN2. In addition, and a second port is added for each of the two three-state wite circuits, which are now designated as 404-1 through 404-4 (and xD 1, xI1, xD2 and xI2) in FIG. 4. The additional ports 404-2, 404-4 have data inputs labeled “I” in FIG. 4, and are enabled by control signal “A.”

As is the case for the “D” input ports, where the enable signal “C” is fed to a duplicate inverter stage 408-1 (xCN1) and 408-2 (xCN2), the enable signal “A” is also fed to a duplicate inverter stage 408-3 (xAN1) and 408-4 (xAN2). The new local clock tree circuits xAN1 and xAN2 each drive unique nodes AN1 (coupled to the gate of transistor TA1 in circuit xI1) and AN2 (coupled to the gate of transistor TA2 in xI2) such that xI1 and xI2 cannot both be turned on by a single glitch in just one of either xAN1 or xAN2 associated with the A clock. Again, the same protection applies to new local C clock tree circuits xCN1 and xCN2; i.e., a single glitch in just one of either xCN1 or xCN2 does not turn on both xD1 and xD2, since CN1 is coupled to the gate of transistor TD1 in xD1 and CN2 is coupled to the gate of transistor TD2 in xD2.

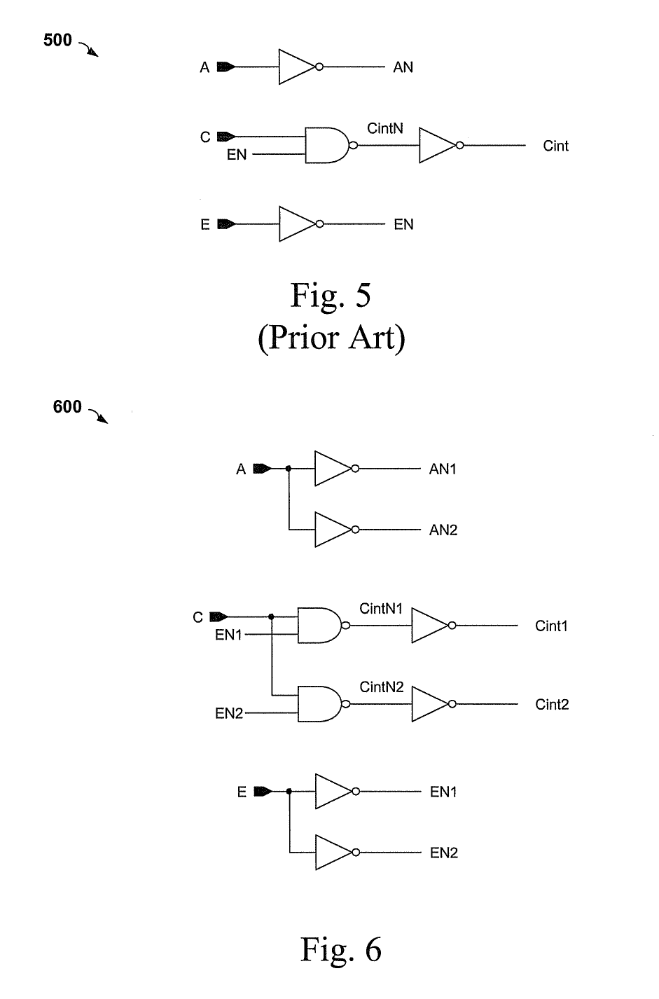

FIGS. 5 and 6 illustrate a comparison of set of existing local control signals for a dual port, master/slave flip-flop and a corresponding set of duplicate control signals in accordance with the inventive embodiments discussed herein. In FIG. 5, a conventional scan port has enable signal A and complement signal AN, with the enable signal for the slave port labeled signal E with complement signal EN. The functional port has true/complement enable signals Cint and CintN locally generated by both input pins C and E.

In contrast, FIG. 6 illustrates the local clock tree duplication for each of the control signals A, E, CintN, and Cint, wherein signals AN1 and AN2 are generated from A; signals EN1 and EN2 are generated from E; and Cint1 and Cint2 are generated from C and EN1, En2, respectively. Similar to the description in conjunction with Figure e, nodes EN1 and EN2 are separated to prevent a glitch on the E inverter from upsetting the slave. AN1 and AN2 remain separated as in the discussion with respect to FIG. 4. Not only are Cint1 and Cint2 separated, and CintN1 and CintN2 separated, but the respective NAND gates driving CintN1 and CintN2 have unique “E complement” inputs EN1 and EN2. When E=1, the slave should be opaque; however, a high-going glitch on E complement will briefly make the master transparent. The two NAND gates cannot share a node that could have a glitch.

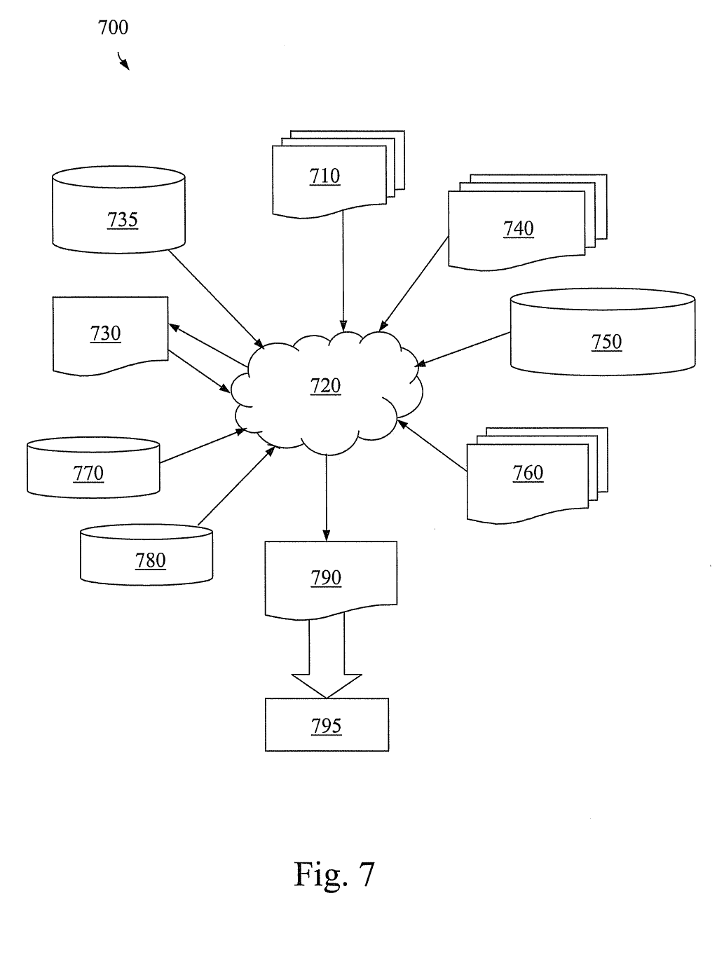

FIG. 7 is a block diagram illustrating an example of a design flow 700. Design flow 700 may vary depending on the type of IC being designed. For example, a design flow 700 for building an application specific IC (ASIC) will differ from a design flow 700 for designing a standard component. Design structure 710 is preferably an input to a design process 720 and may come from an IP provider, a core developer, or other design company or may be generated by the operator of the design flow, or from other sources. Design structure 710 comprises circuit embodiments 300, 400, 600 in the form of schematics or HDL, a hardware-description language, (e.g., Verilog, VHDL, C, etc.). Design structure 710 may be contained on one or more machine readable medium(s). For example, design structure 710 may be a text file or a graphical representation of circuit embodiments 300, 400, 600 illustrated in FIGS. 3, 4 and 6. Design process 720 synthesizes (or translates) circuit embodiments 300, 400, 600 into a netlist 730, where netlist 730 is, for example, a list of wires, transistors, logic gates, control circuits, I/O, models, etc., and describes the connections to other elements and circuits in an integrated circuit design and recorded on at least one of a machine readable medium. This may be an iterative process in which netlist 730 is resynthesized one or more times depending on design specifications and parameters for the circuit.

Design process 720 includes using a variety of inputs; for example, inputs from library elements 735 which may house a set of commonly used elements, circuits, and devices, including models, layouts, and symbolic representations, for a given manufacturing technology (e.g., different technology nodes, 32 nm, 45 nm, 90 nm, etc.), design specifications 740, characterization data 750, verification data 760, design rules 770, and test data files 780, which may include test patterns and other testing information. Design process 720 further includes, for example, standard circuit design processes such as timing analysis, verification tools, design rule checkers, place and route tools, etc. One of ordinary skill in the art of integrated circuit design can appreciate the extent of possible electronic design automation tools and applications used in design process 720 without deviating from the scope and spirit of the invention. The design structure of the invention embodiments is not limited to any specific design flow.

Design process 720 preferably translates embodiments of the invention as shown in FIGS. 3, 4 and 6, along with any additional integrated circuit design or data (if applicable), into a second design structure 790. Second design structure 790 resides on a storage medium in a data format used for the exchange of layout data of integrated circuits (e.g. information stored in a GDSII (GDS2), GL1, OASIS, or any other suitable format for storing such design structures). Second design structure 790 may comprise information such as, for example, test data files, design content files, manufacturing data, layout parameters, wires, levels of metal, vias, shapes, data for routing through the manufacturing line, and any other data required by a semiconductor manufacturer to produce embodiments of the invention as shown in FIGS. 3, 4 and 6. Second design structure 790 may then proceed to a stage 795 where, for example, second design structure 790: proceeds to tape-out, is released to manufacturing, is released to a mask house, is sent to another design house, is sent back to the customer, etc.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. An apparatus for improving storage latch susceptibility to single event upsets (SEUs), comprising:
a dual interconnected storage cell (DICE) configured within a storage latch circuit;
a pair of separate three-state circuits configured to write the DICE latch, with each three-state circuit coupled to separate data nodes within the DICE latch; and
a pair of local clock circuits configured within the storage latch circuit, the pair of local clock circuits configured to generate a duplicate pair of control signals that separately control a corresponding one of the pair of the separate three-state circuits configured to write the DICE latch;
wherein in the event of a charge accumulation event on only one of the pair of local clock circuits so as to change the logical state of the corresponding control signal, the presence of the other of the pair of local clock circuits that remains unaffected by the charge accumulation event prevents an error in the logical state of the DICE latch.

2. The apparatus of claim 1, wherein both of the pair of local clock circuits receive a common input signal thereto.

3. The apparatus of claim 1, wherein the separate data nodes within the DICE latch to which the pair of separate three-state circuits are respectively coupled comprise nodes of the same logical polarity.

4. The apparatus of claim 1, wherein the storage latch circuit comprises a master/slave flip-flop.

5. The apparatus of claim 1, wherein the storage latch circuit comprises a two-port latch having a first and a second pair of three-state write circuits.

6. The apparatus of claim 5, wherein both the first and second pair of three-state write circuits each have a pair of local clock circuits configured within the storage latch circuit, each pair of local clock circuits configured to generate a duplicate pair of control signals that separately control a corresponding one of the first and second pair of the separate three-state circuits.

7. The apparatus of claim 2, wherein the duplicate pair of control signals simultaneously arrive at the specific three-state circuit associated therewith.

8. A design structure embodied in a machine readable medium used in a design process, the design structure comprising:
an apparatus for improving storage latch susceptibility to single event upsets (SEUs), the apparatus including a dual interconnected storage cell (DICE) configured within a storage latch circuit;
a pair of separate three-state circuits configured to write the DICE latch, with each three-state circuit coupled to separate data nodes within the DICE latch; and
a pair of local clock circuits configured within the storage latch circuit, the pair of local clock circuits configured to generate a duplicate pair of control signals that separately control a corresponding one of the pair of the separate three-state circuits configured to write the DICE latch;
wherein in the event of a charge accumulation event on only one of the pair of local clock circuits so as to change the logical state of the corresponding control signal, the presence of the other of the pair of local clock circuits that remains unaffected by the charge accumulation event prevents an error in the logical state of the DICE latch.

9. The design structure of claim 8, wherein both of the pair of local clock circuits receive a common input signal thereto.

10. The design structure of claim 8, wherein the separate data nodes within the DICE latch to which the pair of separate three-state circuits are respectively coupled comprise nodes of the same logical polarity.

11. The design structure of claim 8, wherein the storage latch circuit comprises a master/slave flip-flop.

12. The design structure of claim 8, wherein the storage latch circuit comprises a two-port latch having a first and a second pair of three-state write circuits.

13. The design structure of claim 12, wherein both the first and second pair of three-state write circuits each have a pair of local clock circuits configured within the storage latch circuit, each pair of local clock circuits configured to generate a duplicate pair of control signals that separately control a corresponding one of the first and second pair of the separate three-state circuits.

14. The design structure of claim 9, wherein the duplicate pair of control signals simultaneously arrive at the specific three-state circuit associated therewith.

15. The design structure of claim 9, wherein the design structure comprises a netlist describing the apparatus for improving storage latch susceptibility to SEUs.

16. The design structure of claim 9, wherein the design structure resides on storage medium as a data format used for the exchange of layout data of integrated circuits.

17. The design structure of claim 9, wherein the design structure includes at least one of test data files, characterization data, verification data, programming data, or design specifications.

18. A method for improving storage latch susceptibility to single event upsets (SEUs), the method comprising:
configuring a dual interconnected storage cell (DICE) configured within a storage latch circuit;
configuring a pair of separate three-state circuits configured to write the DICE latch, with each three-state circuit coupled to separate data nodes within the DICE latch; and
configuring a pair of local clock circuits configured within the storage latch circuit, the pair of local clock circuits configured to generate a duplicate pair of control signals that separately control a corresponding one of the pair of the separate three-state circuits configured to write the DICE latch;
wherein in the event of a charge accumulation event on only one of the pair of local clock circuits so as to change the logical state of the corresponding control signal, the presence of the other of the pair of local clock circuits that remains unaffected by the charge accumulation event prevents an error in the logical state of the DICE latch.

19. The method of claim 18, wherein the storage latch circuit comprises a master/slave flip-flop.

20. The method of claim 18, wherein the storage latch circuit comprises a two-port latch having a first and a second pair of three-state write circuits.
